(19) United States
(12) Patent Application Publication
(10) Pub. No.: US 2013/0056059 A1
(43) Pub. Date: Mar. 7, 2013

(54) BACK CONTACT LAYER STRUCTURE FOR GROUP IBIIIAVIA PHOTOVOLTAIC CELLS

(71) Applicants: James Freitag, Sunnyvale, CA (US); Mustafa Pinarbasi, Morgan Hill, CA (US)

(72) Inventors: James Freitag, Sunnyvale, CA (US); Mustafa Pinarbasi, Morgan Hill, CA (US)

(21) Appl. No.: 13/541,602

(22) Filed: Jul. 3, 2012

Related U.S. Application Data
(63) Continuation-in-part of application No. 12/875,669, filed on Sep. 3, 2010.

(51) Int. Cl. H01L 31/18; H01L 31/0224

(52) U.S. Cl. 136/256; 438/95; 257/E31.005

(57) ABSTRACT

Described are new ohmic contact materials and diffusion barriers for Group IBIIIAVIA based solar cell structures, which eliminate two way diffusion while preserving the efficient ohmic contacts between the substrate and the absorber layers.

### RELATED APPLICATIONS

This application is a continuation-in-part of U.S. patent application Ser. No. 12/875,669 filed Sep. 3, 2010, for BACK CONTACT DIFFUSION BARRIER LAYERS FOR GROUP IBIIIAVIA PHOTOVOLTAIC CELLS and is hereby incorporated by reference.

### BACKGROUND

1. Field of the Related Art

Described are apparatus and methods of solar cell design and fabrication and, more particularly, to forming contact layers and diffusion barriers for such solar cells.

2. Background

Solar cells are photovoltaic devices that convert sunlight directly into electrical energy. Solar cells can be based on crystalline silicon or thin films of various semiconductor materials, usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost by employing deposition techniques widely used in the thin film industry. Group IBIIIAVIA compound photovoltaic cells including copper indium gallium diselenide (CIGS) based solar cells have demonstrated the greatest potential for high performance, high efficiency, and low cost thin film PV products.

A conventional Group IBIIIAVIA compound solar cell can be built on a substrate that can be a sheet of glass, a sheet of metal, an insulating foil or web, or a conductive foil or web. A contact layer such as a molybdenum (Mo) film is deposited on the substrate as the back electrode of the solar cell. An absorber thin film including a material in the family of Cu(In,Ga)(S,Se)₂, is formed on the conductive Mo film. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or the contact layer formed on the substrate as an absorber precursor, and then reacted with S and/or Se in a high temperature annealing process.

After the absorber film is formed, a transparent layer, for example, a CdS film, a ZnO film or a CdS/ZnO film-stack is formed on the absorber film. The preferred electrical type of the absorber film is p-type, and the preferred electrical type of the transparent layer is n-type. However, an n-type absorber and a p-type window layer can also be formed. The above described conventional device structure is called substrate-type structure. In the substrate structure light enters the device from the transparent layer side. A so called superstrate-type structure can also be formed by depositing a transparent conductive layer on a transparent superstrate such as glass or transparent polymeric foil, and then depositing the Cu(In,Ga)(S,Se)₂ absorber film, and finally forming an ohmic contact to the device by a conductive layer. In the superstrate structure light enters the device from the transparent superstrate side.

In standard CIGS as well as Si and amorphous Si module technologies, the solar cells can be manufactured on flexible conductive substrates such as stainless steel foil substrates. Due to its flexibility, a stainless steel substrate allows low cost roll-to-roll solar cell manufacturing techniques. In such solar cells built on conductive substrates, the transparent layer and the conductive substrate form the opposite poles of the solar cells. Multiple solar cells can be electrically interconnected by stringing or shingling methods that establish electrical connection between the opposite poles of the solar cells. Such interconnected solar cells are then packaged in protective packages to form solar modules or panels. Many modules can also be combined to form large solar panels. The solar modules are constructed using various packaging materials to mechanically support and protect the solar cells in them against mechanical damage. Each module typically includes multiple solar cells which are electrically connected to one another using above mentioned stringing or shingling interconnection methods.

The conversion efficiency of a thin film solar cell depends on many fundamental factors, such as the bandgap value and electronic and optical quality of the absorber layer, the quality of the window layer, the quality of the rectifying junction, and so on. Since the total thickness of the electrically active layers of the CIGS thin film solar cells is in the range of 0.5-5 micrometers, these devices are highly sensitive to defects. Even the sub-micron size defects may influence their illuminated I-V characteristics. A prior art problem associated with manufacturing CIGS thin film devices on stainless steel substrates, however, is the inadvertent introduction of defects into the device structure during the reaction of the absorber precursor. During this step, the constituents of the stainless steel substrate diffuse towards the absorber layer, and Se from the absorber precursor diffuses towards the stainless steel substrate. Despite the advantages of flexible stainless steel substrates in CIGS solar cell applications, during the high temperature anneal, Se from the absorber precursor can diffuse through the Mo contact layer toward the substrate, corrode the stainless steel and form FeSe compounds on the substrate, which cause electrical shunting defects. Such shunting defects introduce a shunting path, between the substrate and the absorber or the transparent layer through which the electrical current of the device may leak. The shunting defects lower the fill factor, the voltage and the conversion efficiency of the solar cells. Also, Mo is highly reactive with Se and, as a result, forms Mo-selenide (MoSe₂) at the interface with the CIGS absorber layer. Although, a very thin MoSe₂ film can help establish ohmic contact between the Mo contact layer and the CIGS layer, which is essential for high conversion efficiency, due to high diffusivity of Se in Mo, MoSe₂ film quickly gets thicker in high process temperatures and reduces Mo contact layer conductivity, and, due to poor adhesion at the metal/selenide interface, increases the likelihood of film delamination, which are unwanted. Furthermore, the atoms of the stainless steel such as iron (Fe) atoms can also diffuse from the substrate into the CIGS absorber by diffusing through the Mo contact layer during the aforementioned high temperature anneal or reaction process that forms the absorber. This unwanted material diffusion significantly degrades the performance of the resulting device.

### SUMMARY

Described herein are new ohmic contact materials and diffusion barriers for Group IBIIIAVIA based solar cell structures, which eliminate two way diffusion while preserving the efficient ohmic contacts between the substrate and the absorber layers.

In one aspect, [apparatus].

In another aspect [method]

These and other aspects and advantages are described further herein.

### BRIEF DESCRIPTION OF THE DRAWINGS

These and other aspects and features will become apparent to those of ordinary skill in the art upon review of the following description of specific embodiments in conjunction with the accompanying figures, wherein:

FIG. 1A is a schematic side view of an embodiment of a solar cell base stack, including a substrate, a back contact and an intermediate layer;

FIG. 1B is a schematic side view of a CIGS absorber precursor layer formed on the solar cell base stack shown in FIG. 1A;

FIG. 1C is a schematic side view after the reaction of the CIGS precursor layer, wherein the reaction have transformed the CIGS precursor layer to a CIGS absorber and the intermediate layer to a metal-selenide layer; and

FIG. 2 is schematic perspective view of an exemplary solar cell employing the structure shown in FIG. 1C.

### DETAILED DESCRIPTION OF THE PREFERRED EMBODIMENTS

The preferred embodiments described herein provide solar cell manufacturing methods and device structures to prevent unwanted material diffusion from a Group IBIIIAVIA thin film absorber material and a substrate and of a solar cell during the manufacture of the solar cell. In one embodiment, a back contact or back electrode is configured as a stack of multiple material layers and formed between a stainless steel substrate and an absorber layer of a solar cell. The back contact includes a diffusion layer to prevent such unwanted material diffusion between the stainless steel substrate and the absorber layer. The absorber layer may be a Cu(In,Ga)(Se,S)₂ or CIGSS compound thin film which is formed by annealing (reacting) an absorber precursor including Cu, In, Ga and Se, and optionally S at a temperature range of about 400-600° C. in a reactor. Accordingly, during the reaction, the back contact inhibits or minimizes both unwanted diffusion mechanisms, namely, the iron (Fe) diffusion from the stainless-steel substrate to the absorber layer and the selenium (Se) diffusion from the absorber layer to the stainless steel. In one embodiment, the back contact includes: a contact layer formed over the stainless steel substrate; a diffusion barrier layer formed on the contact layer; and a transition layer formed on the diffusion layer. The contact layer may be a metal layer including one of Mo, W, Ti, Ta, Cu, and Al, or alloys and multilayers of these metals. The diffusion barrier layer may be a bilayer including TiN and Ru films. The transition layer may be one of MoSe₂, WSe₂, TiSe₂ and TaSe₂. The transition layer may preferably be formed by selenizing a metal layer such as a Mo, W, Ti or Ta layer during CIGS absorber layer formation process. The back contact may also include a metal barrier layer between the substrate and the contact layer, such as a Cr layer, deposited on the stainless steel substrate and a metal nitride barrier layer, such as a TiN layer, deposited on the metal barrier layer.

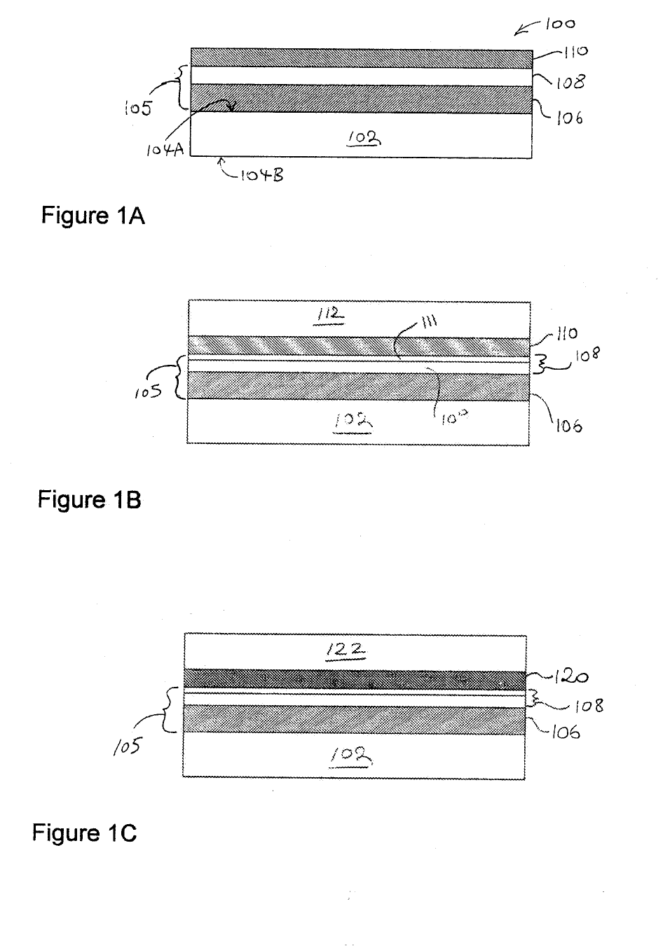

FIG. 1A shows a base 100 including a substrate 102 having a front surface 104A and a back surface 104B, and a back contact stack 105 or back contact formed on the front surface 104A of the flexible substrate 102. The back contact 105 preferably includes multiple conductive films. In one embodiment, the back contact 105 includes: a contact layer 106 formed over the substrate 102; a diffusion barrier layer 108 formed over the contact layer 106. The contact layer 106 may be a Mo layer and deposited onto the substrate 102 which may be flexible conductive substrate or conductive flexible foil such as a stainless-steel flexible foil or sheet. Alternatively, materials such as W, Ta, Ti, Cu and Al may also be used as the contact layer 106. The thickness of the contact layer 106 may be in the range of 100-2000 nm, preferably 300-900 nm. The diffusion barrier layer 108 may include one or more films of Ti, Ta, W, Nb, Ru, and nitrides or various combinations of these materials. In the following step, an intermediate layer 110 is formed over the diffusion barrier layer 108 of the back contact 105. In the preferred embodiment, the intermediate layer 110 may be selected from a group of metals that are reactive with Se and form a selenide providing good ohmic contact between the back contact and the absorber layers. In this respect, the intermediate layer 110 may also be a Mo layer and deposited onto the diffusion barrier layer 108. Alternatively, materials such as W, Ta and Ti may also be used as the intermediate layer 110. The thickness of the intermediate layer 110 may be in the range of 1-50 nm, preferably 2-20 nm. The contact layer 106 and intermediate layer 110 may be the same material or different materials. The contact layer 106 and intermediate layer 110 may preferably be deposited using a PVD process such as a sputtering deposition process.

As shown in FIG. 1B, once the back contact 105 is formed, an absorber precursor layer is formed on the intermediate layer 110 of the back contact. The absorber precursor layer 112 may be a precursor for a Cu(In,Ga)(Se)₂ or a Cu(In)(Se)₂ compound semiconductor absorber. In the preferred embodiment, the absorber precursor layer 112 includes Cu, In, Ga and Se to form a Cu(In,Ga)(Se)₂ compound semiconductor by reacting the absorber precursor layer 112 at a temperature range of 400-600° C. The reaction is a selenization reaction and selenizes Cu, In and Ga metals to form CIGS. As will be described more fully below, during this transformation reaction more Se may be delivered to the absorber precursor layer to form the Cu(In,Ga)(Se)₂ compound semiconductor. The diffusion barrier layer 108 inhibits or minimizes Se diffusion from the absorber precursor layer to substrate during the reaction of the absorber precursor layer 112.

As shown in FIG. 1C, the absorber precursor layer 112 including Cu, In, G and Se is selenized or reacted to form an absorber layer 122 including a Group IBIIIAVIA compound, such as Cu(In,Ga)(Se)₂, or Cu(In,Ga)(S, Se)₂ if S is also included. As the absorber precursor layer 112 is selenized during the reaction, the intermediate layer 110 on top of the back contact stack 105, which is in direct contact with the absorber precursor layer 112, may also be selenized and transformed into a metal-selenide layer 120. The intermediate layer 110 may be fully or partially selenized. The diffusion barrier layer 108 prevents selenium diffusing into the back contact 105 while allowing the metal selenide layer 120, which is desirable to establish good ohmic contact between the back contact 105 and the absorber layer 122, to form at the absorber layer/back contact interface. For example, if a Mo-layer is selected as the intermediate layer 110, the selenization process transforms it into a MoSe₂ layer, i.e., the metal-selenide later 120. For thin intermediate layer thickness, since the diffusion barrier layer 108 limits selenization process only to intermediate layer 110, the thickness of the intermediate layer 110 is the only parameter that determines or controls the thickness of the metal selenide layer 120, which is, as opposed to the prior art processes, independent of the selenization process parameters such as temperature, time and Se vapor pressure. In the prior art, when Mo or other selenizable materials such as W, Ti or Ta is used as a back contact between the absorber and the substrate, due to high diffusivity of Se in such materials, it is very difficult to control the forming MoSe₂ layer during the reaction process of the absorber precursor by controlling the selenization process parameters. Consequently, the reaction process may result in either a very thick MoSe₂ portion between the absorber layer and the remaining Mo contact layer or the Mo contact layer may be entirely selenized and transformed into MoSe₂, which is unwanted and distorts or reduces the electrical conductivity of the back contact layer or the electrode, and increases the likelihood of thin film delamination. By employing a selenizable intermediate layer with a predetermined thickness between the back contact and the precursor stack, the method is independent of the selenization process parameters, such as reaction temperature, time and Se vapor pressure, and therefore allows optimization of the photovoltaic device properties.

As shown in FIGS. 1B-1C, the diffusion barrier layer 108 may include a nitride barrier film 109, which is a metal nitride film, deposited on the contact layer 106, and a nucleation film 111, which may be a platinum group metal film, deposited on the metal nitride film 109. The intermediate layer 110 may be directly deposited on the nucleation film 111 of the diffusion barrier layer 108. The nitride barrier film 109 may include titanium-nitride (TiN), tantalum nitride (TaN), niobium nitride (NbN), or tungsten nitride (WN), and may be fully or partially made of TiN or a combination of the above nitrides. In the preferred embodiment, the nitride barrier film may be a TiN film. The nucleation film 111 may include a metal selected from the platinum group elements such as Ru, Os, Ir or Pt or their alloys thereof. The nucleation film 111 is deposited on the nitride barrier film 109 to form the diffusion barrier layer 108. The nitride barrier film may have thickness preferably in the range of 10-50 nm, and the nucleation film 111 may have a thickness in the range of 1-50 nm. In the preferred embodiment, the nucleation film may be a Ru film or a Ru-alloy film, which is does not react readily with Se to form a selenide. The nucleation film provides improved electrical contact between the intermediate layer and the diffusion barrier and provides improved film adhesion at the selenized intermediate layer and diffusion barrier interface. The nitride barrier film 109 may be deposited using PVD processes such as reactive sputtering processes in a nitrogen-containing atmosphere. The nucleation film 111 may be deposited by techniques such as electroless deposition, electroplating, atomic layer deposition, CVD, MOCVD, and PVD among others. Although the present embodiment demonstrates a two-step selenization process, it can provide the same benefits for other selenization techniques exhibiting high Se activity, i.e., high temperature and/or Se pressure, such as reactive sputtering of Cu, In, and Ga in a Se atmosphere.

The absorber layer 122 may be formed using a two step process including first depositing the precursor layer having Cu, In, Ga and Se, and optionally S, on the intermediate layer 110, and second reacting the precursor layer in a reactor at a temperature range of 300-600° C. in an inert or Se gas and optionally S gas containing atmosphere. Cu, In, Ga and Se may be electroplated to form a precursor stack including one or more films of Cu, In, Ga and Se. Optionally, a stack including Cu, In and Ga films may be first formed by electroplating on the intermediate layer 110 and then one or more Se films may be vapor deposited on the previously formed stack that includes Cu, In and Ga films, or Se and S containing vapor may be introduced into the reaction furnace.

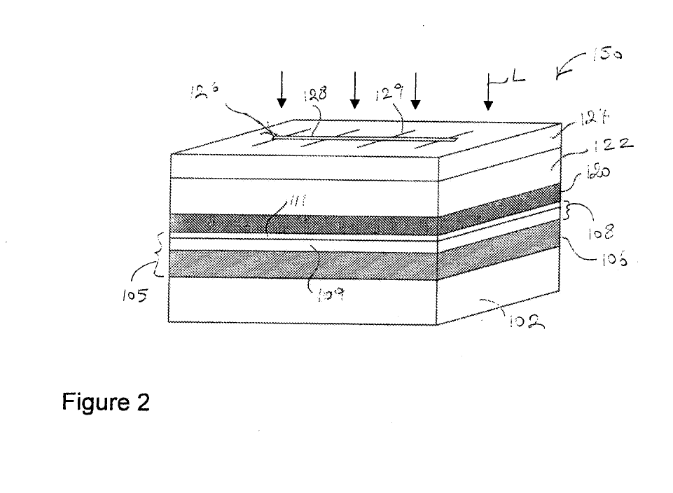

FIG. 2 shows in perspective view a solar cell 150 using the above described structure including the metal selenide layer 120 formed between the back contact 105 and the CIGS absorber layer 122. As shown, in the next step, the transparent layer 124, which may include a buffer-layer/TCO (transparent conductive oxide) stack, is formed on the absorber layer 122. An exemplary buffer material may be a (Cd, Zn)S which is generally electroless deposited on the absorber layer. The TCO layer is deposited on the buffer layer and an exemplary TCO material may be a ZnO layer, an indium tin oxide (ITO) layer or a stack comprising both ZnO and ITO. A conductive grid 126, including a busbar 128 and conductive fingers 129, is disposed on top surface of the transparent layer 124 to collect the current generated when the light depicted by arrows ‘L’ illuminates the top surface of the transparent layer 124. Various layers depicted in the drawings are not necessarily drawn to scale.

Although aspects and advantages of the present are described herein with respect to certain preferred embodiments, modifications of the preferred embodiments will be apparent to those skilled in the art.

We claim:

1. A method of manufacturing a Cu(In,Ga)Se₂ thin-film solar cell on a conductive substrate, comprising:
forming a multilayer back contact on a conductive flexible substrate, wherein the multilayer back contact includes a diffusion barrier layer;
forming an intermediate layer on the diffusion barrier layer, wherein the intermediate layer is a metal layer;
forming an absorber precursor including Cu species, In species, Ga species and Se species over the intermediate layer;
applying heat to the absorber precursor to form therefrom an absorber layer including a Cu(In,Ga)Se₂ thin film compound, wherein the step of forming the absorber layer causes some of the Se species in the absorber layer to diffuse towards the intermediate layer and at least partially transforms the intermediate layer into a metal-selenide layer and wherein the diffusion barrier layer inhibits diffusion of the Se species across the diffusion barrier during the step of applying heat;
disposing a transparent conductive layer on the thin film absorber layer, the transparent layer including a buffer layer deposited on the thin film absorber and a transparent conductive oxide layer formed on the buffer layer; and
forming a top terminal on the transparent conductive layer, thereby resulting in the Cu(In,Ga)Se₂ thin-film solar cell.

2. The method of claim 1, wherein the step of forming a multilayer back contact includes depositing a contact layer including one of molybdenum (Mo), tungsten (W) and titanium (Ti) and tantalum (Ta), and depositing the diffusion barrier layer onto the contact layer.

3. The method of claim 2, wherein the diffusion barrier includes a nitride barrier film formed over the contact layer and a nucleation layer formed over the nitride barrier film.

4. The method of claim 3, wherein the nitride barrier film includes one of titanium-nitride (TiN), tantalum nitride (TaN), and tungsten nitride (WN), and wherein the nucleation film includes one of Ru, Os, Ir and Pt.

5. The method of claim 4, wherein the nitride barrier film titanium-nitride (TiN) film, and wherein the nucleation film is a Ru-film.

6. The method of claim 3, wherein the step of forming the intermediate layer on the diffusion barrier layer includes forming the intermediate layer on the nucleation film.

7. The method of claim 3, wherein the intermediate layer includes one of Mo, W, Ti and Ta.

8. The method of claim 7, wherein the intermediate layer is a Mo-layer.

9. The method of claim 7, wherein the step of applying heat the Mo, W, Ti or Ta layer is selenized and transformed into a MoSe₂, WSe₂, TiSe₂ or TaSe₂ layer.

10. The method of claim 1, wherein the step of forming the absorber precursor comprises: electroplating a film stack including at least a copper (Cu) film, an indium (In) film and a gallium (Ga) film; depositing a selenium (Se) film on the film stack using one of an electroplating process and a vapor deposition process

11. The method of claim 1, wherein the buffer layer includes CdS and the transparent conductive oxide layer includes ZnO.

12. The method of claim 1, wherein the contact layer has a thickness in the range of 100-2000 nm.

13. The method of claim 3, wherein the nucleation film has a thickness in the range of 1-50 nm.

14. The method of claim 3, wherein the nitride barrier film has a thickness in the range of 1-50 nm.

1. A solar cell, comprising:
a flexible conductive substrate;
a back contact formed on the flexible conductive substrate, wherein the back contact includes a contact layer formed on the flexible conductive substrate and a diffusion barrier layer formed on the contact layer;
an ohmic contact layer is formed on the diffusion barrier layer of the back contact, wherein the ohmic contact layer is a metal-selenide layer;
a thin film absorber layer including Cu species, In species, Ga species and Se species formed on the ohmic contact layer;
a transparent layer deposited on the thin film absorber layer, the transparent layer including a buffer layer deposited on the thin film absorber and a transparent conductive oxide layer formed on the buffer layer; and
a top terminal formed on the transparent layer;
wherein the diffusion barrier layer inhibits diffusion of the selenium species from the thin film absorber layer across the diffusion barrier layer.
